(19) United States
(12) Patent Application Publication
(10) Pub. No.: US 2012/0171613 A1
(43) Pub. Date: Jul. 5, 2012

(54) UPPER LAYER FILM-FORMING COMPOSITION AND METHOD OF FORMING PHOTORESIST PATTERN

(75) Inventors: Norihiko SUGIE, Tokyo (JP); Kazunori KUSABIRAKI, Tokyo (JP); Kiyoshi TANAKA, Tokyo (JP); Motoyuki SHIMA, Tokyo (JP); Yoshikazu YAMAGUCHI, Tokyo (JP)

(73) Assignee: JSR Corporation, Tokyo (JP)

(21) Appl. No.: 13/420,525

(22) Filed: Mar. 14, 2012

Related U.S. Application Data
(63) Continuation of application No. PCT/JP2010/065957, filed on Sep. 15, 2010.

(30) Foreign Application Priority Data
Sep. 15, 2009 (JP) 2009-212583

(51) Int. Cl. G03F 7/20; G03F 7/004; G03F 7/00

(52) U.S. Cl. 430/273.1; 430/449; 430/325

(57) ABSTRACT

An upper layer film-forming composition includes a resin and a solvent component. The resin is soluble in a developer. The solvent component includes first solvent which has a boiling point of 180 to 280° C. at 101.3 kPa and a vapor pressure of 0.001 to 0.1 kPa at 20° C. The upper layer film-forming composition is used to form an upper layer film on a photoresist film.

### CROSS-REFERENCE TO RELATED APPLICATIONS

The present application is a continuation application of International Application No. PCT/JP2010/065957, filed Sep. 15, 2010, which claims priority to Japanese Patent Application No. 2009-212583, filed Sep. 15, 2009. The contents of these applications are incorporated herein by reference in their entirety.

### BACKGROUND OF THE INVENTION

1. Field of the Invention

The present invention relates to an upper layer film-forming composition and a method of forming a photoresist pattern.

2. Discussion of the Background

A stepper or step-and-scan projection exposure apparatus that transfers the pattern of a reticle as a photomask to each shot area of a photoresist film formed on a wafer via a projection optical system has been used to produce semiconductor devices and the like. The resolution of the projection optical system provided with the projection exposure apparatus increases as the exposure wavelength of radiation shortens and the numerical aperture of the projection optical system increases. Therefore, the exposure wavelength of radiation used for the projection exposure apparatus has been shortened year by year along with miniaturization of integrated circuits, and the numerical aperture of the projection optical system has also been increased.

The depth of focus is also important as well as the resolution in the case of performing the exposure. The resolution R and the depth of focus δ are given by the following expressions.

R=k1·λ/NA (i)

δ=k2·λ/NA² (ii)

wherein, λ is the exposure wavelength, NA is the numerical aperture of the projection optical system, and k1 and k2 are process coefficients. It may be understood from above expressions that the depth of focus δ increases by using radiation having a shorter wavelength in the case that an identical resolution R is obtained.

A photoresist film is formed on the surface of the wafer to be exposed, and the pattern is transferred to the photoresist film. The space in which the wafer is provided is filled with air or nitrogen in the conventional projection exposure apparatus. When the space between the wafer and the lens of the projection exposure apparatus is filled with an immersion medium having a refractive index of n, the resolution R and the depth of focus δ are given by the following expressions.

R=k1{λ/n}/NA (iii)

δ=k2·nλ/NA² (iv)

For example, in the case of using water as the immersion medium in an ArF process, the refractive index n of light having a wavelength of 193 nm in water is 1.44 and the resolution R becomes 69.4% (R=k1·(λ/1.44)/NA) and the depth of focus becomes 144% (δ=k2·1.44λ/NA²) compared with the case of using air or nitrogen as a medium. Thus, the projection exposure method which makes the wavelength of the radiation shorten by utilizing an immersion medium having a refractive index of n and to transfers a finer pattern is referred to as liquid immersion exposure. Liquid immersion exposure is considered to be essential for miniaturization of lithography, particularly lithography that implements a line width of several tens of nanometers, and a projection exposure apparatus used for liquid immersion exposure has been disclosed (see JP-A-H11-176727, for example).

In the liquid immersion exposure method using water as the immersion medium, the photoresist film applied and formed on the wafer and the lens of the projection exposure apparatus come in contact with water, respectively. Therefore, water may permeate the photoresist film, so that the resolution may decrease. In addition, a component of the photoresist film may be eluted into water, so that the surface of the lens of the projection exposure apparatus may be contaminated. Therefore, there is a method of forming an upper layer film on the photoresist film in order to block off the photoresist film from water (see JP-A-2005-316352, for example). The upper layer film is needed to have sufficient permeability to the exposure wavelength of radiation, and to be able to be formed on the photoresist film being hardly intermixed with the photoresist film. It is also necessary for the upper layer film to be stable, that is elution of a component of the upper layer film into the immersion medium (e.g., water) does not occur during liquid immersion exposure, and to be easily dissolved in a developer (e.g., alkaline aqueous solution).

### SUMMARY OF THE INVENTION

According to one aspect of the present invention, an upper layer film-forming composition includes a resin and a solvent component. The resin is soluble in a developer. The solvent component includes first solvent which has a boiling point of 180 to 280° C. at 101.3 kPa and a vapor pressure of 0.001 to 0.1 kPa at 20° C. The upper layer film-forming composition is used to form an upper layer film on a photoresist film.

According to another aspect of the present invention, a method of forming a photoresist pattern includes forming a photoresist film on a substrate. An upper layer film is formed on the photoresist film using the upper layer film-forming composition. Radiation is applied to the upper layer film and the photoresist film through a mask having a given pattern via an immersion medium. The upper layer film and the photoresist film are developed using a developer to form a photoresist pattern.

### DESCRIPTION OF THE EMBODIMENTS

Specifically, embodiments of the invention provide the following upper layer film-forming composition and method of forming a photoresist pattern.

[1] An upper layer film-forming composition including (A) a resin that is soluble in a developer (hereinafter may be referred to as “resin (A)”), and (B) a solvent component that includes (B1) a solvent having a boiling point of 180 to 280° C. at 101.3 kPa and a vapor pressure of 0.001 to 0.1 kPa at 20° C. (hereinafter may be referred to as “solvent component (B)”), and being used to form an upper layer film on a photoresist film.
[2] The upper layer film-forming composition according to [1], wherein the solvent (B1) is a compound shown by a general formula (1) or γ-butyrolactone,

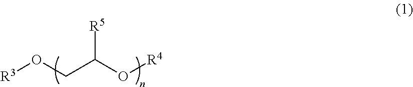

wherein n is an integer from 1 to 4, R³ and R⁴ individually represent a hydrogen atom, an alkyl group, or an acyl group, and R⁵ represents a hydrogen atom or a methyl group.
[3] The upper layer film-forming composition according to [1] or [2], wherein the solvent component (B) further includes (B2) a solvent shown by a general formula (2),

R—OH (2)

wherein R represents a linear, branched, or cyclic hydrocarbon group having 1 to 10 carbon atoms or a halogenated hydrocarbon group.
[4] The upper layer film-forming composition according to any one of [1] to [3], wherein the solvent component (B) further includes (B3) a solvent shown by a general formula (3),

R¹—O—R² (3)

wherein R¹ and R² individually represent a hydrocarbon group having 1 to 8 carbon atoms or a halogenated hydrocarbon group.
[5] The upper layer film-forming composition according to any one of [1] to [4], wherein the solvent (B1) is at least one compound selected from the group consisting of (a) diethylene glycol monoethyl ether acetate, (b) ethylene glycol monobutyl ether acetate, (c) diethylene glycol diethyl ether, (d) γ-butyrolactone, (e) methyl propylene diglycol, and (f) methyl propylene triglycol.
[6] The upper layer film-forming composition according to any one of [1] to [5], wherein the resin (A) includes at least one repeating unit selected from the group consisting of a repeating unit having a group shown by a general formula (4) (hereinafter may be referred to as “repeating unit (4)”), a repeating unit having a group shown by a general formula (5) (hereinafter may be referred to as “repeating unit (5)”), a repeating unit having a group shown by a general formula (6) (hereinafter may be referred to as “repeating unit (6)”), a repeating unit having a carboxyl group (hereinafter may be referred to as “repeating unit (7)”), and a repeating unit having a sulfo group (hereinafter may be referred to as “repeating unit (8)”), and has a polystyrene-reduced weight average molecular weight (hereinafter may be referred to as “Mw”) determined by gel permeation chromatography of 2000 to 100,000,

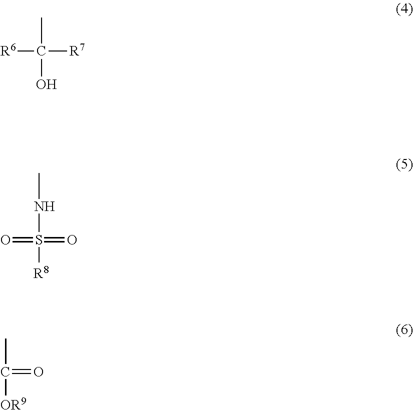

wherein R⁶ and R⁷ individually represent a hydrogen atom, an alkyl group having 1 to 4 carbon atoms, or a fluoroalkyl group having 1 to 4 carbon atoms, provided that at least one of R⁶ and R⁷ represents a fluoroalkyl group having 1 to 4 carbon atoms, R⁸ represents a fluoroalkyl group having 1 to 20 carbon atoms, and R⁹ represents a fluorohydrocarbon group or an organic group having a polar group.
[7] The upper layer film-forming composition according to any one of [1] to [6], further including at least one of an acid component and an acid generating agent that generates an acid upon exposure to radiation (hereinafter may be referred to as “component (C))”).
[8] A method for forming a photoresist pattern including (1) forming a photoresist film on a substrate, (2) forming an upper layer film on the photoresist film using the upper layer film-forming composition according to any one of [1] to [7], and (3) applying radiation to the upper layer film and the photoresist film with a mask having a given pattern via an immersion medium, and then developing the upper layer film and the photoresist film using a developer to form a photoresist pattern.

The upper layer film-forming composition according to the embodiment of the present invention does not dry out inside a nozzle and is hardly to produce a solid between applications during a semiconductor production process.

The method for forming a photoresist pattern according to the embodiment of the present invention makes it possible for liquid immersion exposure method that uses the upper layer film to be suitably used for a semiconductor production process.

Exemplary embodiments of the invention are described below. Note that the invention is not limited to the following exemplary embodiments. It should be understood that various modifications, improvements, and the like may be made of the following exemplary embodiments without departing from the scope of the invention based on common knowledge of a person skilled in the art.

### I. Upper Layer Film-Forming Composition

An upper layer film-forming composition according to the embodiment of the present invention can inhibit the upper layer film-forming composition to dry out inside a nozzle between applications during a semiconductor production process. Therefore, the upper layer film-forming composition needs hardly to clean the nozzle, and to dispose of the upper layer film-forming composition introduced in surplus. Therefore, a rapid production process and a reduction in cost can be implemented.

In the case of using water as the immersion medium, an upper layer film which is formed on a photoresist film by using the upper layer film-forming composition according to the embodiment of the present invention prevents the photoresist film from coming in direct contact with water during liquid immersion exposure, suppresses a deterioration in lithographic performance of the photoresist film due to permeation of water, and prevents contamination of the lens of a projection exposure apparatus due to elution of a component of the photoresist film into water.

### 1. Resin (A)

The resin (A) can form a film stable to the immersion medium (e.g., water) during exposure to radiation, and is soluble in the developer used to form the resist pattern. The expression “film stable to the immersion medium (e.g., water) during exposure to radiation” used in this specification means that the difference of the film thickness between the film thickness in which the coating film having the thickness of 10 to 100 nm is formed on a substrate by using the upper layer film-forming composition and measured with a film thickness meter (e.g., “Lambda Ace VM90” manufactured by Dainippon Screen Mfg. Co., Ltd.)) and the film thickness of the coating film measured after discharging ultrapure water to the substrate from a rinse nozzle of a coater/developer (e.g., “CLEAN TRACK ACT 8” manufactured by Tokyo Electron Ltd.) for 60 seconds, and then spin-drying the substrate at 4000 rpm for 15 seconds, is within 3% of the initial thickness.

The expression “soluble in the developer used to form the resist pattern” used in this specification means that no residue is observed on the resist pattern with the naked eye after development using an alkaline aqueous solution, and removing the upper layer film. That is, the resin (A) is an alkali-soluble resin that is scarcely dissolved in the immersion medium (e.g., water), but is dissolved in an alkaline aqueous solution during development with an alkaline aqueous solution after exposure to radiation.

An upper layer film formed by the upper layer film-forming composition that includes such a resin (A) prevents the photoresist film from coming in direct contact with the immersion medium (e.g., water) during liquid immersion exposure, and suppresses a deterioration in lithographic performance of the photoresist film due to permeation of the immersion medium. Therefore, the upper layer film prevents contamination of the lens of a projection exposure apparatus due to elution of a component of the photoresist film into the immersion medium.

### (1) Component

The resin (A) preferably includes at least one repeating unit selected from the group consisting of the repeating unit (4), the repeating unit (5), the repeating unit (6), the repeating unit (7), and the repeating unit (8).

### (i) Repeating Unit (4)

Among the group represented by R⁶ and R⁷ in the general formula (4), examples of the alkyl group having 1 to 4 carbon atoms include a methyl group, an ethyl group, a propyl group, and a butyl group. Moreover, examples of the fluoroalkyl group having 1 to 4 carbon atoms include a difluoromethyl group, a perfluoromethyl group, a 2,2-difluoroethyl group, a 2,2,2-trifluoroethyl group, a perfluoroethyl group, a 2,2,3,3,-tetrafluoropropyl group, a perfluoroethylmethyl group, a perfluoropropyl group, a 2,2,3,3,4,4-hexafluorobutyl group, a perfluorobutyl group, and the like. Among these, a perfluoromethyl group is preferable.

There is at least an alcoholic hydroxyl group that includes at least one fluoroalkyl group bonded to the carbon atom at the α-position in the side chain of the repeating unit (4). Therefore, the hydrogen atom constituting the alcoholic hydroxyl group in the general formula (4) easily dissociates due to the electron-withdrawing of the fluoroalkyl group (particularly a perfluoromethyl group) to exhibit acidity in an aqueous solution. Therefore, the resin (A) is insoluble in purified water, but is soluble in an alkaline aqueous solution. Examples of a preferable repeating unit (4) include a repeating unit shown by the following general formula (4a).

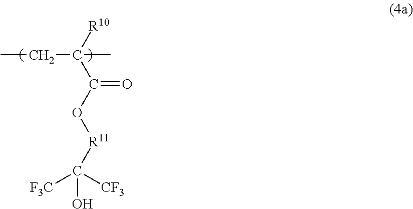

wherein R¹⁰ represents a hydrogen atom or a methyl group, and R¹¹ represents a divalent organic group.

The divalent organic group represented by R¹¹ in the general formula (4a) is preferably a divalent hydrocarbon group, and more preferably a chain-like or cyclic divalent hydrocarbon group. Specific examples of a preferable divalent organic group represented by R¹¹ include chain-like hydrocarbon groups such as a methylene group, an ethylene group, a propylene group (e.g., 1,3-propylene group or 1,2-propylene group), an icosalene group, a 1-methyl-1,3-propylene group, a 2-methyl-1,3-propylene group, an ethylidene group, a 1-propylidene group, and a 2-propylidene group; monocyclic hydrocarbon groups such as a cycloalkylene group having 3 to 10 carbon atoms (e.g., cyclobutylene group (e.g., 1,3-cyclobutylene group), cyclopentylene group (e.g., 1,3-cyclopentylene group), and cyclooctylene group); bridged cyclic hydrocarbon groups such as a cyclic hydrocarbon group including 2 to 4 rings and having 4 to 30 carbon atoms (e.g., norbornylene group (e.g., 1,4-norbornylene group and 2,5-norbornylene group) and adamantylene group (e.g., 1,5-adamantylene group and 2,6-adamantylene group); and the like.

In the case that R¹¹ represents a divalent alicyclic hydrocarbon group, it is preferable that an alkanediyl group having 1 to 4 carbon atoms is inserted as a spacer between the bis(trifluoromethyl)hydroxymethyl group and the alicyclic hydrocarbon group. The divalent organic group represented by R¹¹ in the general formula (4a) is particularly preferably a hydrocarbon group including a 2,5-norbornylene group or a 2,6-norbornylene group, or a 1,2-propylene group.

### (ii) Repeating Unit (5)

Specific examples of the fluoroalkyl group having 1 to 20 carbon atoms represented by R⁸ in the general formula (5) include a difluoromethyl group, a perfluoromethyl group, a 2,2-difluoroethyl group, a 2,2,2-trifluoroethyl group, a perfluoroethyl group, a perfluoroethylmethyl group, a perfluoropropyl group, a perfluorobutyl group, a 1,1-dimethyl-2,2,3,3-tetrafluoropropyl group, a 2-(perfluoropropyl)ethyl group, a perfluoropentyl group, a perfluorohexyl group, a perfluorohexylmethyl group, a perfluoroheptyl group, a 2-(perfluorohexyl)ethyl group, a perfluoroheptylmethyl group, a perfluorooctyl group, a 2-(perfluoroheptyl)ethyl group, a perfluorooctylmethyl group, a perfluorononyl group, a 2-(perfluorooctyl)ethyl group, a perfluorononylmethyl group, a perfluorodecyl group, and the like. Among these, a perfluoromethyl group, a perfluoroethyl group, a perfluoropropyl group, a perfluorobutyl group, and a perfluorooctyl group are particularly preferable. This is because that the acidity of the hydrogen atom bonded to the nitrogen atom becomes moderate.

Examples of a preferable repeating unit (5) include a repeating unit shown by the following general formula (5a).

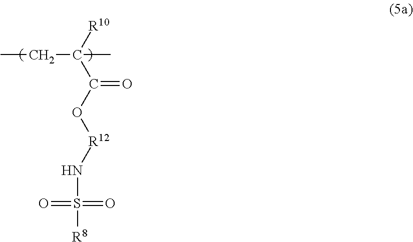

wherein R⁸ represents a fluoroalkyl group having 1 to 20 carbon atoms, R¹⁰ represents a hydrogen atom or a methyl group, and R¹² represents a divalent organic group.

Examples of the divalent organic group represented by R¹² in the general formula (5a) include the groups mentioned above in connection with R¹¹ in the general formula (4a).

In the case that R¹² represents a divalent alicyclic hydrocarbon group, it is preferable that an alkanediyl group having 1 to 4 carbon atoms is inserted as a spacer between the —NH— group and the alicyclic hydrocarbon group. The divalent organic group represented by R¹² in the general formula (5a) is particularly preferably a hydrocarbon group including a 2,5-norbornylene group or a 1,5-adamantylene group, an ethylene group, or a 1,3-propylene group.

(iii) Repeating Unit (6)

The fluorohydrocarbon group or the organic group having a polar group represented by R⁹ in the general formula (6) is preferably a fluorohydrocarbon group having 1 to 20 carbon atoms or a monovalent hydrocarbon group having 1 to 20 carbon atoms and having a polar group (provided that a group that falls under the repeating unit (4) is excluded).

Examples of a preferable repeating unit (6) include a repeating unit shown by the following general formula (6a).

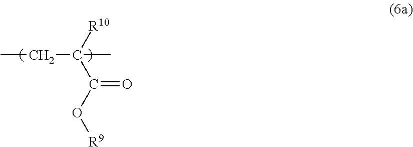

wherein R⁹ is a residue of an alcohol that is bonded to (meth)acrylic acid via an ester bond, and represents a fluorohydrocarbon group or an organic group having a polar group, and R¹⁹ represents a hydrogen atom or a methyl group.

In the organic group having the polar group represented by R⁹, examples of the polar group include a hydroxyl group, an amino group, and a cyano group.

Specific examples of a preferable group represented by R⁹ in the general formula (6a) include a hydroxymethyl group, a 1-hydroxyethyl group, a 2-hydroxyethyl group, a 1-hydroxypropyl group, a 2-hydroxypropyl group, a 3-hydroxypropyl group, a 2-hydroxybutyl group, a 2,3-dihydroxypropyl group, an aminomethyl group, a 1-aminoethyl group, a 2-aminoethyl group, a 1-aminopropyl group, a 2-aminopropyl group, a 3-aminopropyl group, a difluoromethyl group, a perfluoromethyl group, a 2,2-difluoroethyl group, a 2,2,2-trifluoroethyl group, a perfluoroethyl group, a 1-(perfluoromethyl)ethyl group, a perfluoropropyl group, a perfluoropropylmethyl group, a perfluorobutyl group, a perfluoropentyl group, a perfluorohexyl group, a perfluoroheptyl group, a perfluorooctyl group, a perfluorononyl group, a perfluorodecyl group, a (2,2,2-trifluoroethyl)-α-cyano group, a (perfluoroethylmethyl)-α-cyano group, a (2,2,3,3,3-pentafluoropropyl)-2-ethoxy group, and a (2,2,3,3,3-pentafluoropropyl)-2-cyano group.

The repeating unit (6) may be a repeating unit derived from radically polymerizable monomer having a cyano group (e.g., acrylonitrile or methacrylonitrile), or radically polymerizable monomer having an amide bond (e.g., acrylamide or methacrylamide).

### (iv) Repeating Unit (7)

Examples of the repeating unit (7) include a repeating unit derived from a radically polymerizable monomer having a carboxyl group. Specific examples of the radically polymerizable monomer having a carboxyl group include unsaturated monocarboxylic acids such as (meth)acrylic acid, crotonic acid, cinnamic acid, atropic acid, 3-acetyloxy(meth)acrylic acid, and 3-benzoyloxy(meth)acrylic acid; unsaturated polycarboxylic acids such as fumaric acid and maleic acid; monoalkyl esters such as monomethyl esters, monoethyl esters, mono-n-propyl esters, and mono-n-butyl esters of unsaturated polycarboxylic acids; 2-(meth)acrylamide-2-methylpropanecarboxylic acid, 2-α-carboxyacrylamide-2-methylpropanecarboxylic acid, (2,2,2-trifluoroethyl)-α-carboxyl group, a (perfluoroethylmethyl)-α-carboxyl group, a (2,2,2-trifluoroethyl)-α-carboxymethyl group, and the like.

Specific examples of a preferable radically polymerizable monomer having a carboxyl group include a radically polymerizable monomer shown by the following general formula (7).

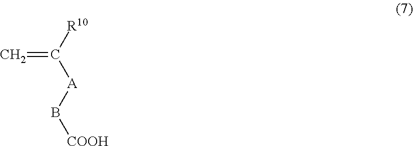

wherein R¹⁰ represents a hydrogen atom or a methyl group, A represents a single bond, a carbonyl group, a carbonyloxy group, or an oxycarbonyl group, and B represents a single bond or a divalent organic group having 1 to 20 carbon atoms.

Examples of the group represented by B in the general formula (7) include the groups mentioned above in connection with R¹¹ in the general formula (4a), and arylene groups such as a phenylene group and a tolylene group. The repeating unit (7) is preferably a repeating unit derived from (meth)acrylic acid, crotonic acid, or 2-methacryloyloxyethyl hexahydrophthalate.

### (v) Repeating Unit (8)

Examples of the repeating unit (8) include a repeating unit derived from a radically polymerizable monomer having a sulfo group. Specific examples of the radically polymerizable monomer having a sulfo group include a monomer shown by the following general formula (8).

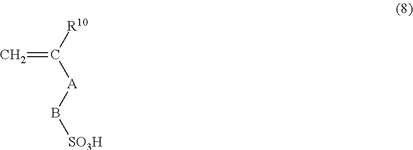

wherein R¹⁰ represents a hydrogen atom or a methyl group, A represents a single bond, a carbonyl group, a carbonyloxy group, or an oxycarbonyl group, and B represents a single bond or a divalent organic group having 1 to 20 carbon atoms.

Examples of a preferable radically polymerizable monomer shown by the general formula (8) include vinylsulfonic acid, allylsulfonic acid, 2-(meth)acrylamido-2-methyl-1-propanesulfonic acid, and 4-vinyl-1-benzenesulfonic acid. Among these, vinylsulfonic acid and allylsulfonic acid are particularly preferable.

### (vi) Other Repeating Unit

The resin (A) may be produced by copolymerizing an other radically polymerizable monomer with the above monomers in order to control the molecular weight, the glass transition temperature, the solubility in the solvent component (B), and the like of the resin (A). The term “other radically polymerizable monomer” used herein refers to a radically polymerizable monomer other than the above mentioned radically polymerizable monomers. A monomer having an acid-labile group may also be copolymerized with the above monomers.

Examples of the other radically polymerizable monomer or the monomer having acid-labile group include alkyl (meth)acrylates such as methyl (meth)acrylate, ethyl (meth)acrylate, n-butyl (meth)acrylate, sec-butyl (meth)acrylate, tert-butyl (meth)acrylate, and isopropyl (meth)acrylate; unsaturated dicarboxylic diesters such as diethyl maleate, diethyl fumarate, and diethyl itaconate; aryl (meth)acrylates such as phenyl (meth)acrylate and benzyl (meth)acrylate; aromatic vinyl compounds such as styrene, α-methylstyrene, m-methylstyrene, p-methylstyrene, vinyltoluene, and p-methoxystyrene; fatty acid vinyls such as vinyl acetate; radically polymerizable monomers having a chlorine atom such as vinyl chloride and vinylidene chloride; and conjugated diolefins such as butadiene, isoprene, and 1,4-dimethylbutadiene. Among these, alkyl (meth)acrylates are preferable. These monomers may be used either individually or in combination.

### Content Ratio of Each Repeating Unit

The upper layer film-forming composition according to the embodiment of the present invention may include only one type of the resin (A), or may include two or more types of the resin (A). The content ratio of the repeating unit (4) or the repeating unit (5) in the resin (A) is preferably 10 mol % or more, more preferably 20 mol % or more, and particularly preferably 30 mol % or more. If the content ratio of the repeating unit is within the above range, the resin (A) exhibits solubility in an alkaline aqueous solution which is developer to prevent a situation in which the upper layer film cannot be removed, and the residue may occur on the resist pattern after development. The upper limit of the content ratio of the repeating unit (4) or the repeating unit (5) is not particularly limited, but is normally 90 mol % or less.

In the case that the resin (A) includes the repeating units (6) to (8), the content ratio of each of the repeating unit is preferably 50 mol % or less, more preferably 40 mol % or less, and particularly preferably 20 mol % or less, respectively. If the content ratio of the repeating units (6) to (8) is within the above range, the resin (A) exhibits water repellency and solubility in a developer in a well-balanced manner. The lower limit of the content ratio of each of the repeating units (6) to (8) is not particularly limited, but is normally 0.5 mol % or more.

In the case that the other polymerizable monomer are copolymerized, the content ratio of a repeating unit derived from the other radically polymerizable monomer in the resin (A) is preferably 50 mol % or less, and more preferably 40 mol % or less. If the content ratio of a repeating unit derived from the other radically polymerizable monomer is 50 mol % or less, it is preferable that the possibility in which the resin (A) exhibits insufficient solubility in an alkaline aqueous solution which is developer, the upper layer film cannot be removed, and the residue may occur on the resist pattern after development may be reduced. The lower limit of the content ratio of a repeating unit derived from the other radically polymerizable monomer is not particularly limited, but is normally 0.5 mol % or more.

### Water-Repellent Resin (A′)

The upper layer film-forming composition according to the embodiment of the present invention may include a water-repellent resin (A′) in addition to the resin (A). When the upper layer film-forming composition according to the embodiment of the present invention includes the resin such an embodiment together with the solvent component (B), it is possible to increase the receding contact angle of the resulting upper layer film. It is preferable that such an upper layer film has the advantages that droplets rarely remain on the upper layer film even when liquid immersion exposure is performed while moving the exposure device at high speed, for example.

Specific examples of the water-repellent resin (A′) include a resin that includes 30 to 80 mol % (preferably 40 to 70 mol %) of the repeating unit (6) wherein R⁹ represents a fluorohydrocarbon group (hereinafter may be referred to as “repeating unit (6-1)”). If the content ratio of the repeating unit (6-1) is within the above range, it is preferable that an upper layer film having a high receding contact angle can be obtained.

The water-repellent resin (A′) may include 20 to 70 mol % of the repeating unit (4) or the repeating unit (5), and 10 mol % or less (preferably 5 mol % or less) of the repeating unit (6) wherein R⁹ represents an organic group having a polar group (hereinafter may be referred to as “repeating unit (6-2)”), the repeating unit (7), or the repeating unit (8), respectively.

When using the resin (A) together with the water-repellent resin (A′), a resin that includes each repeating unit within the above content range (hereinafter may be referred to as “resin (A1)”) may be used as the resin (A). A resin that includes 95 mol % or less of the repeating unit (7), 10 mol % or less of the repeating unit (8), and 50 mol % or less of the repeating unit (4) or the repeating unit (5) (hereinafter may be referred to as “resin (A2)”) may also be used as the resin (A). Note that the resin (A2) may include 30 mol % or less (preferably 10 mol % or less) of the repeating unit (6-1), and may include 95 mol % or less of the repeating unit (6-2).

When using the resin (A) together with the water-repellent resin (A′), the resin (A1) or (A2) may be used either individually or in combination. Two or more one types of the resin (A1) may be used in combination as the resin (A1). This also applies to the resin (A2).

### (2) Production Method

The production method of resin (A) is not particularly limited, and the resin (A) can be produced by an arbitrary known polymerization method. For example, the resin (A) may be produced in a polymerization solvent by radical polymerization using a radical initiator.

Examples of the polymerization solvent include alcohols, cyclic ethers, alkyl ethers of polyhydric alcohols, alkyl ether acetates of polyhydric alcohols, aromatic hydrocarbons, ketones, and esters. Among these, cyclic ethers, alkyl ethers of polyhydric alcohols, alkyl ether acetates of polyhydric alcohols, ketones, and esters are preferable.

Examples of the radical initiator include azo compounds such as 2,2′-azobisisobutyronitrile, 2,2′-azobis-(2-methyl methylpropionate), 2,2′-azobis-(2,4-dimethylvaleronitrile), 2,2′-azobis-(4-methoxy-2-dimethylvaleronitrile); organic peroxides such as benzoyl peroxide, lauroyl peroxide, tert-butyl peroxypivalate, 1,1′-bis-(tert-butylperoxy)cyclohexane; hydrogen peroxide, and the like. When using a peroxide as the radical initiator, a reducing agent may be used in combination with the peroxide to use as a redox-type radical initiator.

### (3) Property Value

The Mw of the resin (A) is preferably 2000 to 100,000, more preferably 2500 to 50,000, and particularly preferably 3000 to 20,000. If the Mw of the resin (A) is within the above range, it is preferable that resin (A) exhibits sufficient water resistance and mechanical properties as the upper layer film, and sufficient solubility in the solvent component (B). The ratio (Mw/Mn) of the Mw to the polystyrene-reduced number average molecular weight (hereinafter referred to as “Mn”) of the resin (A) determined by gel permeation chromatography is preferably 1 to 5, and more preferably 1 to 3.

It is preferable that the content of the impurity such as halogens and metals is as low as possible in the resin (A). This is because the applicability as the upper layer film and uniform solubility in the developer can be further improved. The purification method of the resin (A) include chemical purification such as washing with water or liquid-liquid extraction, or a combination of chemical purification and physical purification such as ultrafiltration or centrifugation, for example.

### 2. Solvent Component (B)

The solvent component (B) included in the upper layer film-forming composition dissolves the resin (A), and includes the solvent (B1) as an essential component. The upper layer film-forming composition according to the embodiment of the present invention can inhibit to dry out inside a nozzle between applications during a semiconductor production process since the solvent component (B) includes the solvent (B1).

The amount of the solvent component (B) may be adjusted depending on the thickness of the upper layer film to be formed, but is normally 1000 to 10,000 parts by mass based on 100 parts by mass of the resin (A).

### (1) Solvent (B1)

The solvent (B1) is preferably a compound shown by the general formula (1) or γ-butyrolactone.

In the group represented by R³ or R⁴ in the general formula (1), examples of a preferable alkyl group include a methyl group, an ethyl group, a propyl group, an isopropyl group, a butyl group, a hexyl group, a 2-ethylhexyl group, a cyclohexyl group, and an adamantyl group. Specific examples of a preferable acyl group include an acetyl group. Specific examples of a preferable aryl group include a phenyl group. Specific examples of a preferable arylalkyl group include a benzyl group. Specific examples of a preferable alkenyl group include an allyl group.

Among these solvent (B1), it is preferably at least one compound selected from the group consisting of (a) diethylene glycol monoethyl ether acetate, (b) ethylene glycol monobutyl ether acetate, (c) diethylene glycol diethyl ether, (d) γ-butyrolactone, (e) methyl propylene diglycol, and (f) methyl propylene triglycol.

The content ratio of the solvent (B1) in the solvent component (B) is preferably 1 to 15 mass %, more preferably 3 to 12 mass %, and particularly preferably 5 to 10 mass %. If the content ratio of the solvent (B1) is within the above range, it is preferable to inhibit the upper layer film-forming composition to dry out inside a nozzle between applications during a semiconductor production process. Moreover, it is also preferable that a loss of the resist film can be suppressed when applying the upper layer film-forming composition to the resist film, and then removing the upper layer film using a developer.

The solvent component (B) preferably includes (B2) a solvent shown by the general formula (2), and more preferably includes (B3) a solvent shown by the general formula (3).

### (2) Solvent (B2)

The solvent (B2) is a monohydric alcohol, preferably a monohydric alcohol having 4 to 8 carbon atoms, and more preferably 2-methyl-1-propanol, 1-butanol, 2-butanol, 1-pentanol, 4-methyl-2-hexanol, 2-pentanol, 3-pentanol, 3-methyl-2-pentanol, 4-methyl-2-pentanol, 2-ethyl-1-butanol, or 2,4-dimethyl-3-pentanol.

The content ratio of the solvent (B2) in the solvent component (B) is preferably 10 to 75 mass %, more preferably 10 to 60 mass %, and particularly preferably 10 to 40 mass %. If the content ratio of the solvent (B2) is within the above range, it is preferable that the amount of foreign matter in the liquid does not increase, and the amount of the composition applied does not increase.

### (3) Solvent (B3)

The solvent (B3) is an ether compound. Specific examples of the solvent (B3) include dipropyl ether, diisopropyl ether, butyl methyl ether, butyl ethyl ether, butyl propyl ether, dibutyl ether, diisobutyl ether, tert-butyl methyl ether, tert-butyl ethyl ether, tert-butyl propyl ether, di-tert-butyl ether, dipentyl ether, diisoamyl ether, cyclopentyl methyl ether, cyclohexyl methyl ether, cyclopentyl ethyl ether, cyclohexyl ethyl ether, cyclopentyl propyl ether, cyclopentyl 2-propyl ether, cyclohexyl propyl ether, cyclohexyl 2-propyl ether, cyclopentyl butyl ether, cyclopentyl tert-butyl ether, cyclohexyl butyl ether, and cyclohexyl-tert-butyl ether.

The content ratio of the solvent (B3) in the solvent component (B) is preferably 20 to 80 mass %, more preferably 40 to 80 mass %, and particularly preferably 50 to 80 mass %. If the content ratio of the solvent (B3) is within the above range, the amount of the composition applied can be reduced and the amount of foreign matter in the liquid does not increase.

The solvent component (B) may include a solvent (hereinafter may be referred to as “solvent (B4)”) other than the solvents (B1) to (B3). Specific examples of the solvent (B4) include cyclic ethers such as tetrahydrofuran and dioxane; aromatic hydrocarbons such as benzene, toluene, and xylene; ketones such as acetone, methyl ethyl ketone, methyl isobutyl ketone, cyclohexanone, 4-hydroxy-4-methyl-2-pentanone, and diacetone alcohol; esters such as ethyl acetate, butyl acetate, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, and methyl 3-ethoxypropionate. Among these, cyclic ethers, ketones, esters, and water are preferable.

The content ratio of the solvent (B4) in the solvent component (B) is preferably 75 mass % or less. If the content ratio of the solvent (B4) is 75 mass % or less, the amount of the upper layer film-forming composition required for homogeneously applying the upper layer-forming composition onto a silicon wafer can be reduced. The lower limit of the content ratio of the solvent (B4) is not particularly limited, but is normally 0.5 mass % or more.

However, the content ratio of some solvents, such as tetrahydrofuran or methyl ethyl ketone that erodes the photoresist film, in the solvent component (B) is preferably 30 mass % or less, and more preferably 20 mass % or less. If the content ratio of some solvents exceeds 30 mass %, photoresist film may be eroded to occur the problems such as intermixing with the upper layer film. As a result, the resolution of the photoresist may significantly deteriorate. The lower limit of the content ratio of some solvents is not particularly limited, but is normally 0.5 mass % or more.

### 3. Component (C)

It is preferable that the upper layer film-forming composition according to the embodiment of the present invention further include the component (C) in order to improve the lithographic performance of the photoresist, and the like. The acid component and the acid generating agent may be used either individually or in combination, respectively.

The amount of the component (C) is preferably 10 parts by mass or less, more preferably 0.001 to 5 parts by mass, and particularly preferably 0.005 to 3 parts by mass, based on 100 parts by mass of the resin (A). If the amount of the component (C) exceeds 10 parts by mass, a component of the upper layer film-forming composition may be eluted into the immersion medium, so that the lens of a projection exposure apparatus may be contaminated.

### (1) Acid Component

Examples of the acid component include carboxylic acids and sulfonic acids. Specific examples of a preferable acid component include acetic acid, propionic acid, butanoic acid, pentanoic acid, hexanoic acid, heptanoic acid, octanoic acid, nonanoic acid, decanoic acid, undecanoic acid, lauryl acid, tridecanoic acid, myristic acid, pentadecanoic acid, palmitic acid, heptadecanoic acid, stearic acid, 2-methylpropionic acid, 2-ethylbutanoic acid, 2-methylbutanoic acid, 3-methylbutanoic acid, 2,2-dimethylbutanoic acid, tert-butylacetic acid, (±)-2-methylpentanoic acid, 2-propylpentanoic acid, 3-methylpentanoic acid, 4-methylpentanoic acid, 2-methylhexanoic acid, (±)-2-ethylhexanoic acid, 2-methylheptane acid, 4-methyloctanoic acid, oxalic acid, malonic acid, methylmalonic acid, ethylmalonic acid, butylmalonic acid, dimethylmalonic acid, succinic acid, methylbutanedioic acid, 2,2-dimethylbutanedioic acid, 2-ethyl-2-methylbutanedioic acid, 2,3-dimethylbutanedioic acid, glutaric acid, 2-methylglutaric acid, 3-methylglutaric acid, 2,3-dimethylglutaric acid, 2,4-dimethylglutaric acid, 3,3-dimethylglutaric acid, adipic acid, 3-methyladipic acid, 2,2,5,5-tetramethyladipic acid, pimelic acid, suberic acid, azelaic acid, sebacic acid, 1,11-undecanedicarboxylic acid, undecanedioic acid, 1,12-dodecanedicarboxylic acid, hexadecanedioic acid, 1,2,3-propanetricarboxylic acid, 2-methyl-1,2,3-propanetricarboxylic acid, 1,2,3,4-butanetetracarboxylic acid,

difluoroacetic acid, trifluoroacetic acid, pentafluoropropionic acid, heptafluorobutanoic acid, hexafluoroglutaric acid, 10-hydroxydecanoic acid, 12-hydroxydodecanoic acid, 12-hydroxystearic acid, citric acid, (−)-menthoxyacetic acid, thiolacetic acid, thiopivalic acid, (methylthio)acetic acid, thiodiglycolic acid, (±)-2-(carboxymethylthio)butanedioic acid, 2,2′,2″,2′″-[1,2-ethanediylidenetetrakis(thio)]tetrakisacetic acid, (±)-3-methyl-2-oxopentanoic acid, 5-oxohexanoic acid, 6-oxoheptanoic acid, 2-oxopentanedioic acid, 2-oxohexanedioic acid, 4-oxoheptanedioic acid, 5-oxononanedioic acid, cyclopentanecarboxylic acid, cyclopentylacetic acid, 3-cyclopentylpropionic acid, cyclohexylacetic acid, dicyclohexylacetic acid, cyclohexanepropionic acid, cyclohexanebutanoic acid, cyclohexanepentanoic acid, (±)-2-methyl-1-cyclohexanecarboxylic acid, (±)-3-methyl-1-cyclohexanecarboxylic acid, 4-methylcyclohexanecarboxylic acid, 4-tert-butylcyclohexanecarboxylic acid, trans-4-pentylcyclohexanecarboxylic acid, 4-methylcyclohexaneacetic acid, 3-methoxycyclohexanecarboxylic acid, 4-methoxycyclohexanecarboxylic acid, cycloheptanecarboxylic acid,

2-norbornaneacetatic acid, [1R-(2-endo,3-exo)]-3-hydroxy-4,7,7-trimethylbicyclo[2.2.1]heptane-2-acetic acid, (+)-camphorcarboxylic acid, (−)-camphorcarboxylic acid, cis-bicyclo[3.3.0]octane-2-carboxylic acid, anti-3-oxotricyclo[2.2.1.0^{2,6}]heptane-7-carboxylic acid, 3-noradamantanecarboxylic acid, 1-adamantanecarboxylic acid, 1-adamantaneacetic acid, 3-methyl-1-adamantaneacetic acid, trans-DL-1,2-cyclopentanedicarboxylic acid, 1,1-cyclopentanediacetic acid, (1S,3R)-(−)-camphoric acid, (±)-trans-1,2-cyclohexanedicarboxylic acid, (±)-1,3-cyclohexanedicarboxylic acid, 1,4-cyclohexanedicarboxylic acid, 1,3-adamantanedicarboxylic acid, 1,3,5-cyclohexanetricarboxylic acid, (1α,3α,5α)-1,3,5-trimethyl-1,3,5-cyclohexanetricarboxylic acid, (1α,3α,5β)-1,3,5-trimethyl-1,3,5-cyclohexanetricarboxylic acid, cis,cis,cis,cis-1,2,3,4-cyclopentanetetracarboxylic acid, 1,2,3,4,5,6-cyclohexanehexacarboxylic acid,

benzoic acid, phenylacetic acid, 2-phenylpropionic acid, 3-phenylpropionic acid, α-fluorophenylacetic acid, 3-phenoxypropionic acid, (±)-2-phenoxypropionic acid, (±)-α-methoxyphenylacetic acid, o-tolylacetic acid, 1,2-phenylenediacetic acid, 1,2,3,4-tetrahydro-2-naphthoic acid, (α,α,α-trifluoro-o-tolyl)acetic acid, 2-fluorophenylacetic acid, 2-methoxyphenylacetic acid, 2-nitrophenylacetic acid, 3-(2-nitrophenyl)-2-oxopropionic acid, (α,α,α-trifluoro-m-tolyl)acetic acid, 3-nitrophenylacetic acid, 3-fluorophenylacetic acid, 4-fluorophenylacetic acid, (α,α,α-trifluoro-p-tolyl)acetic acid, 4-nitrophenylacetic acid, 4-fluorophenoxyacetic acid, 2,6-difluorophenylacetic acid, 2,4-difluorophenylacetic acid, 2,5-difluorophenylacetic acid,

3,4-difluorophenylacetic acid, 3,5-difluorophenylacetic acid, 3,5-bis(trifluoromethyl)phenylacetic acid, 3-fluoro-4-hydroxyphenylacetic acid, (2,5-dimethoxyphenyl)acetic acid, 4-hydroxy-3-nitrophenylacetic acid, 2,3,4,5,6-pentafluorophenylacetic acid, 1-naphthylacetic acid, 2-naphthylacetic acid, (1-naphthoxy)acetic acid, (2-naphthoxy)acetic acid, 2-fluorobenzoic acid, 2-trifluoromethylbenzoic acid, 2-nitrobenzoic acid, 3-fluorobenzoic acid, 3-trifluoromethylbenzoic acid, 3-methoxybenzoic acid, 4-fluorobenzoic acid, 4-trifluoromethylbenzoic acid, 4-nitrobenzoic acid, 3-fluoro-2-methylbenzoic acid, 2,3-difluorobenzoic acid, 2,6-difluorobenzoic acid, 2-fluoro-6-trifluoromethylbenzoic acid, 2-fluoro-3-trifluoromethylbenzoic acid, 2,6-bis(trifluoromethyl)benzoic acid, 2-methyl-6-nitrobenzoic acid, 3-methyl-2-nitrobenzoic acid, 2-methyl-3-nitrobenzoic acid, 5-fluoro-2-methylbenzoic acid, 3-fluoro-4-methylbenzoic acid, 2,4-bis(trifluoromethyl)benzoic acid, 2,5-bis(trifluoromethyl)benzoic acid, 2,4-difluorobenzoic acid, 3,4-difluorobenzoic acid, 2-fluoro-4-trifluoromethylbenzoic acid, 2,5-difluorobenzoic acid, 3-fluoro-4-methoxybenzoic acid, 5-methyl-2-nitrobenzoic acid, 4-methyl-3-nitrobenzoic acid, 3-methyl-4-nitrobenzoic acid, 2-methyl-5-nitrobenzoic acid, 2-fluoro-5-nitrobenzoic acid, 4-fluoro-3-nitrobenzoic acid, 4-methoxy-3-nitrobenzoic acid, 3-methoxy-4-nitrobenzoic acid, 3-hydroxy-4-nitrobenzoic acid, 2-hydroxy-5-nitrobenzoic acid, 2,4-dinitrobenzoic acid, 3,4-dinitrobenzoic acid, 3,5-difluorobenzoic acid, 3,5-bis(trifluoromethyl)benzoic acid, 3,5-dinitrobenzoic acid,

2,3,4-trifluorobenzoic acid, 2,3,6-trifluorobenzoic acid, 2,4,6-trifluorobenzoic acid, 3,4,5-trifluorobenzoic acid, 4-methyl-3,5-dinitrobenzoic acid, 4-hydroxy-3,5-dinitrobenzoic acid, 3,5-dinitrosalicylic acid, 2,4,5-trifluorobenzoic acid, 2,3,4,5-tetrafluorobenzoic acid, 2,3,5,6-tetrafluorobenzoic acid, 2,3,5,6-tetrafluoro-4-methylbenzoic acid, pentafluorobenzoic acid, 2,3,4,5,6-pentafluorophenoxyacetic acid, 1-naphthalenecarboxylic acid, 2-naphthalenecarboxylic acid, 4-fluoro-1-naphthalenecarboxylic acid, 1-hydroxy-2-naphthalenecarboxylic acid, 2-hydroxy-1-naphthalenecarboxylic acid, 3-hydroxy-2-naphthalenecarboxylic acid, 1,4-dihydroxy-2-naphthalenecarboxylic acid, 3,5-dihydroxy-2-naphthalenecarboxylic acid, 1,4-napthalenedicarboxylic acid, 2,3-napthalenedicarboxylic acid, 2,6-napthalenedicarboxylic acid,

5-sulfosalicylic acid, methanesulfonic acid, ethanesulfonic acid, taurine, 3-[(1,1-dimethyl-2-hydroxyethyl)amino]-2-hydroxy-1-propanesulfonic acid, 3-[bis(2-hydroxyethyl)amino]-2-hydroxy-1-propanesulfonic acid, (1R)-(−)-10-camphorsulfonic acid, (1S)-(+)-10-camphorsulfonic acid, trifluoromethanesulfonic acid, perfluorobutanesulfonic acid, perfluorooctanesulfonic acid, (methylamino)sulfonic acid, (butylamino)sulfonic acid, 1,1,2,2-tetrafluoro-2-(tetracyclo[6.2.1.1^{3,6}.0^{2,7}]dodecan-8-yl)ethanesulfonic acid, 1,1-difluoro-2-(tetracyclo[6.2.1.1^{3,6}.0^{2,7}]dodecan-8-yl)ethanesulfonic acid, and the like. These acid components may be used either individually or in combination.

### (2) Acid Generating Agent

Examples of the acid generating agent include sulfonimide compounds, disulfonylmethane compounds, onium salt compounds, sulfone compounds, sulfonate compounds, diazomethane compounds, and the like.

### Sulfonimide Compound

Examples of the sulfonimide compounds include a compound shown by the following general formula (9).

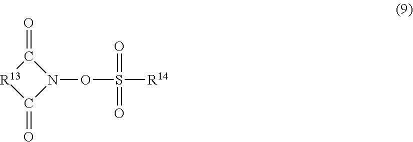

wherein R¹³ represents a divalent organic group, and R¹⁴ represents a monovalent organic group.

Examples of the monovalent organic group represented by R¹⁴ in the general formula (9) include a substituted or unsubstituted linear or branched alkyl group, a substituted or unsubstituted cycloalkyl group, a substituted or unsubstituted aryl group, a perfluoroalkyl group, and the like. Examples of the divalent organic group represented by R¹³ include a substituted or unsubstituted alkylene group, a substituted or unsubstituted alkenylene group, a substituted or unsubstituted phenylene group, and the like.

Specific examples of the sulfonimide compound include N-(trifluoromethylsulfonyloxy)succinimide, N-(trifluoromethylsulfonyloxy)bicyclo[2.2.1]hept-5-ene-2,3-dicarboxylmide, N-(10-camphorsulfonyloxy)succinimide, N-(10-camphorsulfonyloxy)bicyclo[2.2.1]hept-5-ene-2,3-dicarboxylmide, N-(p-toluenesulfonyloxy)succinimide, N-(nonafluorobutylsulfonyloxy)bicyclo[2.2.1]hept-5-ene-2,3-dicarboxylmide, N-(benzenesulfonyloxy)bicyclo[2.2.1]hept-5-ene-2,3-dicarboxylmide, N-{(5-methyl-5-carboxymethanbicyclo[2.2.1]hept-2-yl)sulfonyloxy}succinimide, and the like.

### Disulfonylmethane Compound

Examples of the disulfonylmethane compounds include a compound shown by the following general formula (10).

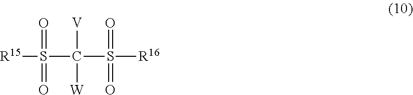

wherein R¹⁵ and R¹⁶ individually represent a linear or branched monovalent aliphatic hydrocarbon group, a cycloalkyl group, an aryl group, an aralkyl group, or a monovalent organic group having a hetero atom, and wherein V and W individually represent an aryl group, a hydrogen atom, a linear or branched monovalent aliphatic hydrocarbon group, or a monovalent organic group having a hetero atom, provided that at least one of V and W represents an aryl group, and V and W may bond to each other to form a monocyclic or polycyclic group having at least one unsaturated bond, or a group shown by the following general formula (10-1).

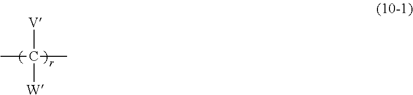

wherein V′ and W′ individually represent a hydrogen atom, a halogen atom, a linear or branched alkyl group, a cycloalkyl group, an aryl group, or an aralkyl group, provided that V′ and W′ bonded to an identical carbon atom or different carbon atoms may bond to each other to form a monocyclic carbon structure, and r is an integer from 2 to 10.

### Onium Salt Compound

Examples of the onium salt compounds include iodonium salts, sulfonium salts, phosphonium salts, diazonium salts, ammonium salts, pyridinium salts, and the like. Specific examples of the onium salt compounds include bis(4-t-butylphenyl)iodonium trifluoromethanesulfonate, bis(4-t-butylphenyl)iodonium perfluoro-n-butanesulfonate, bis(4-t-butylphenyl)iodonium perfluorooctanesulfonate, bis(4-t-butylphenyl)iodonium p-toluenesulfonate, bis(4-t-butylphenyl)iodonium 10-camphorsulfonate, bis(4-t-butylphenyl)iodonium 2-trifluoromethylbenzenesulfonate, bis(4-t-butylphenyl)iodonium 4-trifluoromethylbenzenesulfonate, bis(4-t-butylphenyl)iodonium 2,4-difluorobenzenesulfonate, diphenyliodonium nonafluorobutanesulfonate, diphenyliodonium trifluoromethanesulfonate, diphenyliodonium perfluorooctanesulfonate, diphenyliodonium 10-camphorsulfonate, triphenylsulfonium trifluoromethanesulfonate, triphenylsulfonium perfluoro-n-butanesulfonate, triphenylsulfonium perfluorooctanesulfonate, triphenylsulfonium p-toluenesulfonate, triphenylsulfonium 10-camphorsulfonate, triphenylsulfonium 2-trifluoromethylbenzenesulfonate, triphenylsulfonium 4-trifluoromethylbenzenesulfonate, triphenylsulfonium 2,4-difluoromethylbenzenesulfonate, tri(p-methoxyphenyl)sulfonium trifluoromethanesulfonate, tris(p-methoxyphenyl)sulfonium 10-camphorsulfonate, bis(p-fluorophenyl)iodonium trifluoromethanesulfonate, bis(p-fluorophenyl)iodonium nonafluoromethanesulfonate, bis(p-fluorophenyl)iodonium camphorsulfonate, (p-fluorophenyl)(phenyl)iodonium trifluoromethanesulfonate, tris(p-fluorophenyl)sulfonium trifluoromethanesulfonate, tris(p-fluorophenyl)sulfonium p-toluenesulfonate, (p-fluorophenyl)diphenylsulfonium trifluoromethanesulfonate, 1-(4-n-butoxynaphthyl)tetrahydrothiophenium nonafluoro-n-butanesulfonate, triphenylsulfonium 1,1,2,2-tetrafluoro-2-(tetracyclo[6.2.1.1^{3,6}.0^{2,7}]dodecan-8-yl)ethanesulfonate, triphenylsulfonium 1,1-difluoro-2-(tetracyclo[6.2.1.1^{3,6}.0^{2,7}]dodecan-8-yl)ethanesulfonate, 1-(4-n-butoxynaphthyl)tetrahydrothiophenium 1,1,2,2-tetrafluoro-2-(tetracyclo[6.2.1.1^{3,6}.0^{2,7}]dodecan-8-yl)ethanesulfonate, 1-(4-n-butoxynaphthyl)tetrahydrothiophenium 1,1-difluoro-2-(tetracyclo[6.2.1.1^{3,6}.0^{2,7}]dodecan-8-yl)ethanesulfonate, and the like.

### Sulfone Compound

Examples of the sulfone compounds include β-ketosulfones, β-sulfonylsulfones, α-diazo compounds of these compounds, and the like.

### Sulfonate Compound

Examples of the sulfonate compounds include alkyl sulfonates, haloalkyl sulfonates, aryl sulfonates, imino sulfonates, and the like.

### Diazomethane Compound

Examples of the diazomethane compounds include a compound shown by the following general formula (11).

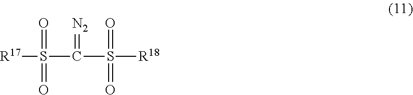

wherein R¹⁷ and R¹⁸ individually represent a monovalent group such as an alkyl group, an aryl group, an alkyl group substituted with a halogen atom, or an aryl group substituted with a halogen atom.

Specific examples of the diazomethane compounds include bis(cyclohexanesulfonyl)diazomethane, bis(3,3-dimethyl-1,5-dioxaspiro[5.5]dodecane-8-sulfonyl)diazomethane, bis(1,4-dioxaspiro[4.5]undecane-7-sulfonyl)diazomethane, bis(t-butylsulfonyl)diazomethane, and the like.

### 4. Surfactant

A surfactant may be included in the upper layer film-forming composition according to the embodiment of the present invention in order to improve the applicability, defoamability, leveling properties, and the like. Examples of the surfactant include commercially available fluorine-based surfactants such as BM-1000, BM-1100 (manufactured by BM Chemie), Megafac F142D, Megafac F172, Megafac F173, Megafac F183 (manufactured by DIC Corporation), Fluorad FC-135, Fluorad FC-170C, Fluorad FC-430, Fluorad FC-431 (manufactured by Sumitomo 3M, Ltd.), Surflon S-112, Surflon S-113, Surflon S-131, Surflon S-141, Surflon S-145 (manufactured by Asahi Glass Co., Ltd.), SH-28PA, SH-190, SH-193, SZ-6032, SF-8428 (manufactured by Dow Corning Toray Silicone Co., Ltd.), FTX-218G, FTX-230G, FTX-240G, FTX-209F, FTX-213F (manufactured by NEOS Co., Ltd.), and the like. The amount of the surfactant is preferably 5 parts by mass or less based on 100 parts by mass of the resin (A). The lower limit of the amount of the surfactant is not particularly limited, but is normally 0.01 parts by mass or more.

### 5. Acid Diffusion Controller

The upper layer film-forming composition according to the embodiment of the present invention may further include an acid diffusion controller in order to improve the lithographic performance of the photoresist. Examples of the acid diffusion controller include a compound shown by the following general formula (12) (hereinafter referred to as “nitrogen-containing compound (I)”), a diamino compound having two nitrogen atoms in the molecule (hereinafter referred to as “nitrogen-containing compound (II)”), a diamino polymer having three or more nitrogen atoms (hereinafter referred to as “nitrogen-containing compound (III)”), an amide group-containing compound, a urea compound, a nitrogen-containing heterocyclic compound, and the like.

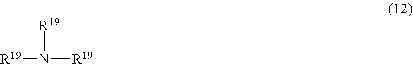

wherein R¹⁹ individually represent a hydrogen atom, a substituted or unsubstituted alkyl group, a substituted or unsubstituted aryl group, or a substituted or unsubstituted aralkyl group.

Specific examples of the nitrogen-containing compound (I) include monoalkylamines such as n-hexylamine, n-heptylamine, n-octylamine, n-nonylamine, and n-decylamine; dialkylamines such as di-n-butylamine, di-n-pentylamine, di-n-hexylamine, di-n-heptylamine, di-n-octylamine, di-n-nonylamine, and di-n-decylamine; trialkylamines such as triethylamine, tri-n-propylamine, tri-n-butylamine, tri-n-pentylamine, tri-n-hexylamine, tri-n-heptylamine, tri-n-octylamine, tri-n-nonylamine, and tri-n-decylamine; trialcoholamines such as triethanolamine and tripropanolamine; aromatic amines such as aniline, N-methylaniline, N,N-dimethylaniline, 2-methylaniline, 3-methylaniline, 4-methylaniline, 4-nitroaniline, diphenylamine, triphenylamine, 1-naphthylamine, 2-(4-aminophenyl)-2-(3-hydroxyphenyl)propane, and 2-(4-aminophenyl)-2-(4-hydroxyphenyl)propane; and the like.

Specific examples of the nitrogen-containing compounds (II) include ethylenediamine, N,N,N′,N′-tetramethylethylenediamine, N,N,N′,N′-tetrakis(2-hydroxypropyl)ethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2′-bis(4-aminophenyl)propane, 2-(3-aminophenyl)-2-(4-aminophenyl)propane, 1,4-bis[1-(4-aminophenyl)-1-methylethyl]benzene, 1,3-bis[1-(4-aminophenyl)-1-methylethyl]benzene, and the like.

Specific examples of the nitrogen-containing compound (III) include polyethyleneimine, polyallylamine, poly(dimethylaminoethylacrylamide), and the like.

Specific examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Specific examples of the urea compound include urea, methylurea, 1,1-dimethylurea, 1,3-dimethylurea, 1,1,3,3-tetramethylurea, 1,3-diphenylurea, tributylthiourea, and the like.

Specific examples of the nitrogen-containing heterocyclic compound include imidazoles such as imidazole, benzimidazole, 4-methylimidazole, 4-methyl-2-phenylimidazole, and 2-phenylbenzimidazole; pyridines such as pyridine, 2-methylpyridine, 4-methylpyridine, 2-ethylpyridine, 4-ethylpyridine, 2-phenylpyridine, 4-phenylpyridine, N-methyl-4-phenylpyridine, nicotine, nicotinic acid, nicotinamide, quinoline, 8-oxyquinoline, and acridine; pyrazine, pyrazole, pyridazine, quinoxaline, purine, pyrrolidine, piperidine, morpholine, 4-methylmorpholine, piperazine, 1,4-dimethylpiperazine, 1,4-diazabicyclo[2.2.2]octane, and the like.

A base precursor having an acid-labile group may also be used as the acid diffusion controller. Specific examples of the base precursor include N-(t-butoxycarbonyl)piperidine, N-(t-butoxycarbonyl)imidazole, N-(t-butoxycarbonyl)benzimidazole, N-(t-butoxycarbonyl)-2-phenylbenzimidazole, N-(t-butoxycarbonyl)dioctylamine, N-(t-butoxycarbonyl)diethanolamine, N-(t-butoxycarbonyl)dicyclohexylamine, N-(t-butoxycarbonyl)diphenylamine, and the like.

Among these, the nitrogen-containing compound (I), the nitrogen-containing heterocyclic compound, and the like are preferable. The trialkylamines is particularly preferable as the nitrogen-containing compound (I), and the imidazoles is particularly preferable as the nitrogen-containing heterocyclic compound. These acid diffusion controllers may be used either individually or in combination.

The amount of the acid diffusion controller is preferably 10 parts by mass or less, more preferably 0.001 to 5 parts by mass, and particularly preferably 0.005 to 3 parts by mass, based on 100 parts by mass of the resin (A). If the amount of the acid diffusion controller exceeds 10 parts by mass, a component of the upper layer film-forming composition may be eluted into the immersion medium, so that the lens of a projection exposure apparatus may be contaminated.

### II. Method for Forming Photoresist Pattern

A method for forming a photoresist pattern according to the embodiment of the present invention includes (1) forming a photoresist film on a substrate, (2) forming an upper layer film on the photoresist film using the upper layer film-forming composition described in the section entitled “I. Upper layer film-forming composition”, and (3) applying radiation to the upper layer film and the photoresist film with a mask having a given pattern via an immersion medium, and then developing the upper layer film and the photoresist film using a developer to form a photoresist pattern. Since the method for forming a photoresist pattern according to the embodiment of the present invention utilizes the upper layer film-forming composition described in the section entitled “I. Upper layer film-forming composition”, when the upper layer film-forming composition is applied onto the substrate, it is suppress that the upper layer film-forming composition dry out inside a nozzle between applications. Therefore, the method may suitably used for a semiconductor production process.

### 1. Step (1)

The step (1) is the step that the photoresist is formed on the substrate. A silicon wafer, an aluminum-coated wafer, or the like may be used as the substrate. An organic or inorganic antireflective film, disclosed in JP-A-H6-12452, for example, may be formed on the substrate in order to maximize the potential of the photoresist film. The photoresist to be used is not particularly limited, but may be appropriately selected depending on the intended purpose of the photoresist. Examples of the photoresist include a chemically-amplified positive-type or negative-type photoresist including an acid generating agent, and the like.

In the method for forming a photoresist pattern according to the embodiment of the present invention, a positive-type photoresist is particularly preferable. In the chemically-amplified positive-type photoresist, the acid-labile group included in the polymer dissociates due to an acid generated by the acid generating agent upon exposure to produce, for example, a carboxyl group. As a result, the solubility of the exposed area of the photoresist film in an alkaline developer increases, and the exposed area is dissolved and removed in the alkaline developer to obtain a positive-type resist pattern.

The photoresist film may be formed by dissolving the polymer for forming the photoresist film, the acid generating agent, and the like in an appropriate solvent so that, for example, the solid content of the solution is 0.1 to 20 mass %, filtering the solution through a filter having a pore size of about 30 nm to obtain a photoresist solution, applying the photoresist solution onto the substrate by an appropriate coating method such as spin coating, cast coating, or roll coating, and then prebaking (hereinafter referred to as “PB”) the applied photoresist solution to volatilize the solvent. A commercially available photoresist solution may be used directly as the photoresist composition.

### 2. Step (2)

The step (2) is the step that the upper layer film is formed by using the upper layer film-forming composition described in the section entitled “I. Upper layer film-forming composition”, and the upper layer film-forming composition is applied onto the photoresist film and then baked again to form the upper layer film. The upper layer film is formed in order to protect the photoresist film and to prevent contamination of the lens of a projection exposure apparatus due to elution of a component of the photoresist film into the immersion medium. The reflection suppression effect on the upper boundary face of the photoresist film increases as the thickness of the upper layer film becomes closer to an odd multiple of λ/4m (wherein X, represents the wavelength of radiation, and m represents the refractive index of the upper layer film). Therefore, it is preferable that the thickness of the upper layer film is close to an odd multiple of λ/4m. Note that the PB step after applying the photoresist solution or the baking step after applying the upper layer film-forming composition may be omitted in order to simplify the process.

### 3. Step (3)

The step (3) is the step that radiation is applied to the upper layer film and the photoresist film (hereinafter referred to as “exposure”) with a mask having a given pattern via an immersion medium, and then the upper layer film and the photoresist film are developed using a developer to form a photoresist pattern.

The immersion medium provided over the photoresist film and the upper layer film may be water for which the pH is adjusted, but is particularly preferably purified water.

Radiation may be appropriately selected from visible rays, ultraviolet rays such as a g-line and an i-line, far-ultraviolet rays such as excimer laser light, X-rays such as synchrotron radiation, charged particle rays such as electron beams, and the like depending on the combination of the photoresist film and the upper layer film. It is particularly preferable to use ArF excimer laser light (wavelength: 193 nm) or KrF excimer laser light (wavelength: 248 nm).

It is preferable to perform post-exposure bake (hereinafter referred to as “PEB”) after exposure in order to improve the resolution, the pattern shape, the developability, and the like of the photoresist film. The PEB temperature is appropriately adjusted depending on the photoresist to be used and the like, but is normally about 30 to 200° C., and preferably 50 to 150° C.

The photoresist film is then developed using the developer, and rinsed to form the desired resist pattern. In this case, it is unnecessary to perform the other removing step, and the upper layer film is completely removed during development or rinsing after development.

Examples of the developer used for development include an alkaline aqueous solution prepared by dissolving sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo-[5.4.0]-7-undecene, 1,5-diazabicyclo-[4.3.0]-5-nonene), or the like in water. An appropriate amount of a water-soluble organic solvent (e.g., alcohol such as methanol or ethanol) or a surfactant may be added to the developer. In the case of developing the photoresist film by using an alkaline aqueous solution, the photoresist film is normally rinsed with water after development.

### EXAMPLES

The invention is further described below by way of examples. Note that the invention is not limited to the following examples. In the examples and comparative examples, the unit “parts” refers to “parts by mass”, and the unit “%” refers to “mass %”, unless otherwise specified. The property values (properties) were measured and evaluated by the following methods.

### Evaluation on Defects Due to Drying Out Inside Nozzle

A 12-inch silicon wafer was subjected to a hexamethyldisilazane (HMDS) treatment at 100° C. for 60 seconds using a coater/developer (1) (“CLEAN TRACK ACT 12” manufactured by Tokyo Electron Ltd.). The upper layer film-forming composition was spin-coated onto the 12-inch silicon wafer using the coater/developer (1) utilizing cyclohexanone as a solvent bath thinner, and prebaked (PB) (90° C., 60 seconds) to form a coating film having a thickness of 30 nm. The number of coating defects was measured using a surface defect inspection system (“KLA2351” manufactured by KLA-Tencor), and the upper layer film-forming composition was installed so that the number of coating defects measured was 100 or less.

After a given time had elapsed without dummy dispensing, the upper layer film-forming composition to be installed was again spin-coated onto the 12-inch silicon wafer, and prebaked (PB) (90° C., 60 seconds) to form a coating film having a thickness of 30 nm. The number of coating defects was then measured using above surface defect inspection system, in the case where the number of coating defects was 100 or less was evaluated as “Acceptable”, and in the case where the number of coating defects was more than 100 was evaluated as “Unacceptable”.

### Film Loss (nm)

The photoresist composition was spin-coated onto an 8-inch silicon wafer which was subjected to an HMDS treatment (100° C., 60 seconds) using a coater/developer (2) (“CLEAN TRACK ACT 8” manufactured by Tokyo Electron Ltd.). The 8-inch silicon wafer was prebaked (PB) at 90° C. for 60 seconds on a hot plate to form a coating film (photoresist film) having a thickness of 120 nm. The upper layer film-forming composition was spin-coated onto the resultant photoresist film, and prebaked (PB) (90° C., 60 seconds) to form an upper layer film having a thickness of 90 nm. The upper layer film was then removed by performing puddle development (developer: 2.38% tetramethylammonium hydroxide aqueous solution (hereinafter may be referred to as “TMAH aqueous solution”)) using the LD nozzle of the coater/developer (2). Note that the upper film is removed by development, but the photoresist film remained in site on the wafer since the photoresist film was not exposed. The thickness of the photoresist film was measured before and after development using a spectroscopic film thickness measurement system (“Rambda Ace VM90” manufactured by Dainippon Screen Mfg. Co., Ltd.), and the amount of change in thickness was taken as the film loss. It is preferable that the value of the film loss is small.

### Measurement of Receding Contact Angle

The photoresist composition was spin-coated onto an 8-inch silicon wafer, and prebaked (PB) at 90° C. for 60 seconds on a hot plate to form a coating film (photoresist film) having a thickness of 120 nm. The receding contact angle was immediately measured by the following method at a temperature of 23° C. (room temperature) and a humidity of 45% under atmospheric pressure using a contact angle meter (“DSA-10” manufactured by KRUS).

The position of the wafer stage of the contact angle meter was adjusted, and the wafer was placed on the stage adjusted. After injecting water into the needle, the position of the needle was adjusted to the initial position at which a water droplet can be formed on the wafer. After water droplet of 25 μl was formed on the wafer by discharging water to the wafer from the needle, once the needle was removed from the water droplet, and then the needle was moved downward to the initial position to place the needle inside the water droplet again. The water droplet was sucked via the needle for 90 seconds at a rate of 10 μl/min, and the contact angle was measured every second (90 times in total). The average value of twenty contact angles for 20 seconds was calculated after the measured value became stable, and taken as the receding contact angle (°).

### Synthesis Example 1

### Production of Resin (A′-1)

As the monomers used for preparing the resin (A′-1) including the repeating units shown by the following formula (A′-1), a monomer solution (i) was prepared by dissolving 17.43 g of (1,1,1,3,3,3-hexafluoro-2-propyl)methacrylate and 4.25 g of 2,2-azobis(methyl 2-methylpropionate) in 25 g of methyl ethyl ketone, and a monomer solution (ii) was prepared by dissolving 27.74 g of (1,1,1-trifluoro-2-trifluoromethyl-2-hydroxy-4-pentyl)methacrylate in 25 g of methyl ethyl ketone, respectively. A 500 ml of a three-necked flask equipped with a thermometer and a dropping funnel was charged with 100 g of methyl ethyl ketone, and purged with nitrogen for 30 minutes. After purging with nitrogen, the liquid contained in the flask was heated to 80° C. with stirring using a magnetic stirrer. The monomer solution (i) to be prepared was added dropwise to the flask over 20 minutes using the dropping funnel, aged for 20 minutes, and the monomer solution (ii) to be prepared was then added dropwise to the flask over 20 minutes. After the reaction was performed for 1 hour, the resultant was cooled to 30° C. or less to obtain a copolymer solution.

The copolymer solution to be obtained was concentrated to 150 g, and transferred to a separating funnel. 50 g of methanol and 400 g of n-hexane were added to the separating funnel to perform the separation and the purification. The lower layer solution thus separated was collected. The lower layer solution to be collected was replaced with 4-methyl-2-pentanol to obtain a resin solution. The solid content (%) of the sample (resin solution) after replacing with 4-methyl-2-pentanol was calculated by weighing 0.3 g of the resin solution on an aluminum dish, heating the resin solution at 140° C. for 1 hour on a hot plate, and using the mass of the resin solution before heating and the mass of the residue (after heating). The solid content was utilized for preparation of the upper layer film-forming composition and calculation of the yield.

The copolymer contained in the resin solution to be obtained had an Mw of 5730 and an Mw/Mn of 1.23, and the yield was 26%. The content ratio of repeating units derived from (1,1,1,3,3,3-hexafluoro-2-propyl)methacrylate and the content ratio of repeating units derived from (1,1,1-trifluoro-2-trifluoromethyl-2-hydroxy-4-pentyl)methacrylate in the copolymer were 61.1 mol % and 38.9 mol %, respectively. The copolymer is referred to as “resin (A′-1)”.

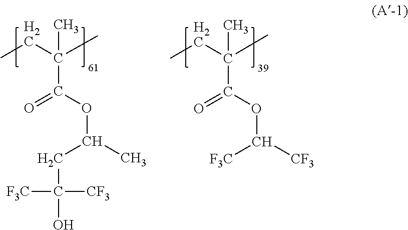

### Synthesis Example 2

### Production of Resin (A1-1)

As the monomer used for preparing the resin (A1-1) including the repeating units shown by the following formula (A1-1), a monomer solution was prepared by dissolving 46.95 g (85 mol %) of (1,1,1-trifluoro-2-trifluoromethyl-2-hydroxy-4-pentyl)methacrylate and 6.91 g of 2,2′-azobis(methyl 2-methylpropionate) which is polymerization initiator in 100 g of isopropyl alcohol (hereinafter referred to as “IPA”). A 500 ml of a three-necked flask equipped with a thermometer and a dropping funnel was charged with 50 g of IPA, and purged with nitrogen for 30 minutes. After purging with nitrogen, the liquid contained in the flask was heated to 80° C. with stirring using a magnetic stirrer. The monomer solution to be prepared was added dropwise to the flask over 2 hours using the dropping funnel. After the addition, the reaction was further performed for 1 hour. After the 10 g of an IPA solution prepared by dissolving 3.05 g (15 mol %) of vinylsulfonic acid in IPA was added dropwise to the flask over 30 minutes, the reaction was further performed for 1 hour. The mixture was then cooled to 30° C. or less to obtain a copolymer solution.

The copolymer solution to be obtained was concentrated to 150 g, and transferred to a separating funnel. 50 g of methanol and 600 g of n-hexane were added to the separating funnel to perform the separation and the purification. The lower layer solution thus separated was collected. The lower layer solution was diluted with IPA so that the amount of the diluted solution was 100 g, and transferred to a separating funnel again. 50 g of methanol and 600 g of n-hexane were added to the separating funnel to perform the separation and the purification. The lower layer solution thus separated was collected. The lower layer solution was replaced with 4-methyl-2-pentanol so that the total amount of the mixture was 250 g. After the replacement, 250 g of water was added to the mixture to perform the separation and the purification, the upper layer solution was collected. The upper layer solution was replaced with 4-methyl-2-pentanol to obtain a resin solution. The solid content of the resin solution was calculated in the same manner as in Synthesis Example 1.

The copolymer contained in the resin solution to be obtained had an Mw of 9760 and an Mw/Mn of 1.51, and the yield was 65%. The content ratio of repeating units derived from (1,1,1-trifluoro-2-trifluoromethyl-2-hydroxy-4-pentyl)methacrylate and the content ratio of repeating units derived from vinylsulfonic acid in the copolymer were 95 mol % and 5 mol %, respectively. The copolymer is referred to as “resin (A1-1)”.

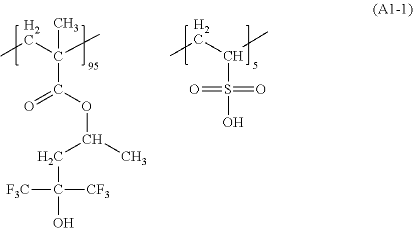

### Synthesis Example 3

### Production of Resin (A2-1)

As the monomer used for preparing the resin (A2-1) including the repeating units shown by the following formula (A2-1), a monomer solution was prepared by dissolving 46.95 g (85 mol %) of 2-methacryloyloxyethyl hexahydrophthalate and 6.91 g of 2,2′-azobis(methyl 2-methylpropionate) which is initiator in 100 g of IPA. A 500 ml of a three-necked flask equipped with a thermometer and a dropping funnel was charged with 50 g of IPA, and purged with nitrogen for 30 minutes. After purging with nitrogen, the liquid contained in the flask was heated to 80° C. with stirring using a magnetic stirrer. The monomer solution to be prepared was added dropwise to the flask over 2 hours using the dropping funnel. After the addition, the reaction was further performed for 1 hour. After the 10 g of an IPA solution prepared by dissolving 3.05 g (15 mol %) of vinylsulfonic acid in IPA was added dropwise to the flask over 30 minutes, the reaction was further performed for 1 hour. The mixture was then cooled to 30° C. or less to obtain a copolymer solution.

The copolymer solution to be obtained was concentrated to 150 g, and transferred to a separating funnel. 50 g of methanol and 600 g of n-hexane were added to the separating funnel to perform the separation and the purification. The lower layer solution thus separated was collected. The lower layer solution was diluted with IPA so that the amount of the diluted solution was 100 g, and transferred to a separating funnel again. 50 g of methanol and 600 g of n-hexane were added to the separating funnel to perform the separation and the purification. The lower layer solution thus separated was collected. The lower layer solution was replaced with 4-methyl-2-pentanol so that the total amount of the mixture was 250 g. After the replacement, 250 g of water was added to the mixture to perform the separation and the purification, and the upper layer solution was collected. The upper layer solution was replaced with 4-methyl-2-pentanol to obtain a resin solution. The solid content of the resin solution was calculated in the same manner as in Synthesis Example 1.

The copolymer contained in the resin solution to be obtained had an Mw of 11,060 and an Mw/Mn of 1.55, and the yield was 75%. The content ratio of repeating units derived from 2-methacryloyloxyethyl hexahydrophthalate and the content ratio of repeating units derived from vinylsulfonic acid in the copolymer were 95 mol % and 5 mol %, respectively. The copolymer is referred to as “resin (A2-1)”.

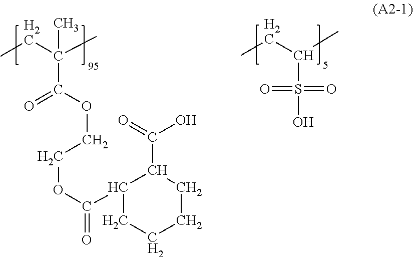

### Synthesis Example 4

### Production of Resin (A′-2)

As the monomers used for preparing the resin (A′-2) including the repeating units shown by the following formula (A′-2), a monomer solution (i) was prepared by dissolving 65.2 g of (1,1,1,3,3,3-hexafluoro-2-propyl)methacrylate and 34.8 g of (1,1,1-trifluoro-2-trifluoromethyl-2-hydroxy-4-pentyl)methacrylate in 95.5 g of methyl ethyl ketone, and a monomer solution (ii) was prepared by dissolving 4.54 g of 2,2-azobis(methyl 2-methylisopropionate) in 4.54 g of methyl ethyl ketone, respectively. A 500 ml of a three-necked flask equipped with a thermometer and a dropping funnel was charged with the monomer solution (i), and purged with nitrogen for 30 minutes. After purging with nitrogen, the liquid contained in the flask was then heated to 75° C. with stirring using a magnetic stirrer. The monomer solution (ii) to be prepared was added dropwise to the flask over 5 minutes using the dropping funnel, and aged for 6 hours. The resultant was cooled to 30° C. or less to obtain a copolymer solution.

The copolymer solution to be obtained was concentrated to 150 g, and transferred to a separating funnel. 150 g of methanol and 750 g of n-hexane were added to the separating funnel to perform the separation and the purification. The lower layer solution thus separated was collected, and transferred to a separating funnel again. 225 g of methanol and 1125 g of n-hexane were added to the separating funnel to perform the separation and the purification. The lower layer solution thus separated was collected, and the lower layer solution was replaced with 4-methyl-2-pentanol to obtain a resin solution. The resin solution to be obtained was transferred to a separating funnel, and 500 g of water was added to the separating funnel to perform the separation and the purification. The upper layer solution thus separated was collected, and the upper layer solution was replaced with 4-methyl-2-pentanol to obtain a resin solution. The solid content (%) of the sample (resin solution) after replacing was calculated by weighing 0.5 g of the resin solution on an aluminum dish, heating the resin solution at 155° C. for 30 minutes on a hot plate, and using the mass of the resin solution before heating and the mass of the residue (after heating). The solid content was utilized for preparation of the upper layer film-forming composition and calculation of the yield.

The copolymer contained in the resin solution obtained had an Mw of 12,800 and an Mw/Mn of 1.8, and the yield was 80%. The content ratio of repeating units derived from (1,1,1,3,3,3-hexafluoro-2-propyl)methacrylate and the content ratio of repeating units derived from (1,1,1-trifluoro-2-trifluoromethyl-2-hydroxy-4-pentyl)methacrylate in the copolymer were 71 mol % and 29 mol %, respectively. The copolymer is referred to as “resin (A′-2)”.

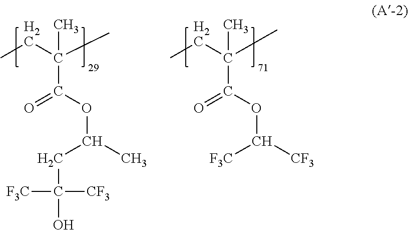

### Synthesis Example 5

### Preparation of Photoresist Composition

53.93 g (50 mol %) of a compound to produce a repeating unit (M-1), 35.38 g (40 mol %) of a compound to produce a repeating unit (M-2), and 10.69 g (10 mol %) of a compound to produce a repeating unit (M-3) were dissolved in 200 g of 2-butanone, and 5.58 g of dimethyl 2,2′-azobis(2-methylpropionate) was further added to the solution to prepare a monomer solution. A 500 ml of three-necked flask equipped with a thermometer and a dropping funnel was charged with 100 g of 2-butanone, and purged with nitrogen for 30 minutes. After purging with nitrogen, the liquid contained in the flask was heated to 80° C. with stirring using a magnetic stirrer. The monomer solution was added dropwise to the flask over 3 hours using the dropping funnel. The polymerization reaction was performed for 6 hours from the start of addition of the monomer solution which regards as the polymerization initiation reaction. After completion of polymerization, the polymer solution was cooled with water to 30° C. or less. After cooling, the polymer solution was added to 2000 g of methanol, and precipitated white powder was filtered off. The white powder to be filtered was washed twice with 400 g of methanol in a slurry state. The white powder was filtered off again, and dried at 50° C. for 17 hours to obtain a white powdery copolymer (74 g, yield: 74%).

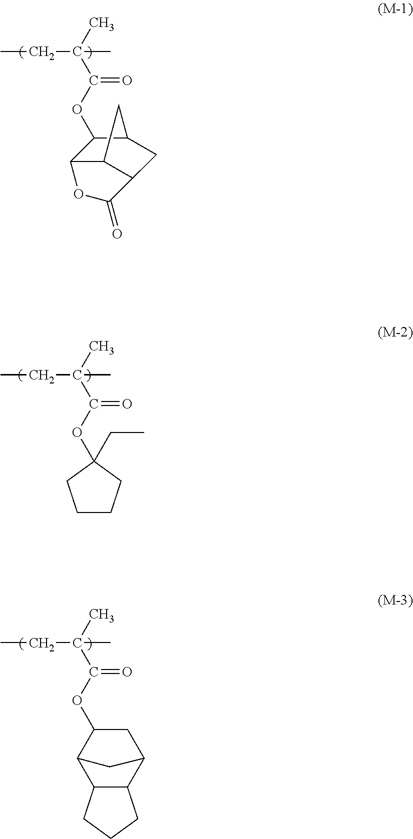

The copolymer had an Mw of 6900 and an Mw/Mn of 1.70. The content ratio of the repeating unit (M-1), the content ratio of the repeating unit (M-2), and the content ratio of the repeating unit (M-3) determined by ¹³C-NMR analysis was 53.0:37.2:9.8 (mol %). The content ratio of repeating units having acid-labile group was 37.2 mol % based on the total repeating units.

100 parts of this copolymer, 1.5 parts of triphenylsulfonium nonafluoro-n-butanesulfonate, 6 parts of 1-(4-n-butoxynaphthalen-1-yl)tetrahydrothiophenium nonafluoro-n-butanesulfonate, 0.65 parts of R-(+)-(tert-butoxycarbonyl)-2-piperidinemethanol, 2400 parts of propylene glycol monomethyl ether acetate, and 30 parts of γ-butyrolactone were mixed so that the total solid content was 0.2 to 20 mass %. The mixture was filtered through a filter having a pore size of 30 nm to obtain a photoresist composition.

### Example 1

As a resin (A), 7 parts of the resin (A′-1) obtained in Synthesis Example 1 and 93 parts of the resin (A1-1) obtained in Synthesis Example 2, and a solvent component (B) including 10 parts of diethylene glycol monoethyl ether acetate as a solvent (B1), 10 parts of 4-methyl-2-pentanol (hereinafter referred to as “MIBC”) as a solvent (B2), and 80 parts of diisoamyl ether (hereinafter referred to as “DIAE”) as a solvent (B3) were mixed to obtain an upper layer film-forming composition. The upper layer film-forming composition to be obtained was evaluated as described above. The film loss according to the photoresist film having receding contact angle of 74° was 4 nm, and the evaluation on defects due to drying out inside the nozzle was “Acceptable”.

### Examples 2 to 12 and Comparative Examples 1 to 4

An upper layer film-forming composition was prepared in the same manner as in Example 1, except that the composition was changed as shown in Table 1. The resulting upper layer film-forming compositions were evaluated as described above. The results are shown in Table 1.

TABLE 1

| | | | | | | Solvent component (B) | | | | | |
|---|---|---|---|---|---|---|---|---|---|---|---|
| | | | | | | Solvent | Solvent | Solvent | Receding | | Evaluation |
| | | | | | Additive | (B2) | (B3) | (B1) | contact | Film | on defects |
| | Resin (A) | | | | (parts | (parts | (parts | (parts | angle | loss | due to drying out |
| | (parts by mass) | | | | by mass) | by mass) | by mass) | by mass) | (°) | (nm) | inside nozzle |
| Ex. 1 | A′-1 (7) | — | A1-1 (93) | — | — | MIBC (10) | DIAE (80) | (a) (10) | 74 | 4 | >2 h, Acceptable |
| Ex. 2 | A′-1 (7) | — | A1-1 (93) | — | Triethylamine (1) | MIBC (10) | DIAE (80) | (a) (10) | 74 | 2 | >2 h, Acceptable |
| Ex. 3 | A′-1 (7) | — | A1-1 (93) | — | 5-Sulfosalicylic | MIBC (10) | DIAE (80) | (a) (10) | 74 | 6 | >2 h, Acceptable |
| | | | | | acid (1) | | | | | | |
| Ex. 4 | A′-1 (7) | — | A1-1 (93) | — | FTX-218G*¹ | MIBC (10) | DIAE (80) | (a) (10) | 74 | 6 | >2 h, Acceptable |
| | | | | | (0.01) | | | | | | |
| Ex. 5 | A′-1 (7) | — | A1-1 (93) | — | — | MIBC (10) | DIAE (75) | (b) (15) | 74 | 5 | >2 h, Acceptable |
| Ex. 6 | A′-1 (7) | — | A1-1 (93) | — | — | MIBC (10) | DIAE (80) | (b) (10) | 74 | 4 | >2 h, Acceptable |
| Ex. 7 | A′-1 (7) | — | A1-1 (93) | — | — | MIBC (10) | DIAE (80) | (c) (10) | 74 | 4 | >2 h, Acceptable |
| Ex. 8 | A′-1 (7) | — | A1-1 (93) | — | — | MIBC (10) | DIAE (80) | (d) (10) | 74 | 4 | >2 h, Acceptable |
| Ex. 9 | A′-1 (7) | — | A1-1 (93) | — | — | MIBC (10) | DIAE (80) | (e) (10) | 74 | 4 | >2 h, Acceptable |
| Ex. 10 | A′-1 (7) | — | A1-1 (93) | — | — | MIBC (10) | DIAE (80) | (f) (10) | 74 | 4 | >2 h, Acceptable |
| Ex. 11 | A′-1 (10) | | A1-1 (70) | A2-1 (20) | — | MIBC (75) | DIAE (20) | (c) (5) | 76 | 6 | >2 h, Acceptable |
| Ex. 12 | — | A′-2 (3) | A1-1 (97) | — | — | MIBC (10) | DIAE (80) | (a) (10) | 74 | 4 | >2 h, Acceptable |
| Comp. | A′-1 (7) | — | A1-1 (93) | — | — | MIBC (20) | DIAE (80) | — | 72 | 3 | 30 min, |
| Ex. 1 | | | | | | | | | | | Unacceptable |
| Comp. | A′-1 (7) | — | A1-1 (93) | — | — | MIBC (60) | DIAE (40) | — | 72 | 4 | 30 min, |
| Ex. 2 | | | | | | | | | | | Unacceptable |
| Comp. | A′-1 (7) | — | A1-1 (93) | — | — | MIBC (10) | DIAE (80) | (g) (10) | 74 | 4 | 30 min, |
| Ex. 3 | | | | | | | | | | | Unacceptable |
| Comp. | A′-1 (7) | — | A1-1 (93) | — | — | MIBC (10) | DIAE (70) | (a) (20) | 75 | 10 | 30 min, |
| Ex. 4 | | | | | | | | | | | Unacceptable |

*¹Fluorine-based surfactant

As is clear from the results shown in Table 1, in the case of using the upper layer film-forming compositions according to the embodiment of the present invention, evaluations on defects due to drying out inside nozzle are “Acceptable” while suppressing a loss of the photoresist film. Therefore, the upper layer film-forming compositions may suitably be used for a semiconductor production process that utilizes liquid immersion exposure. As is clear from the results for Comparative Example 4, in the case of using the solvent component (B) including more than 15 mass % of the solvent (B1), it is understood that defects due to drying out inside the nozzle occurred along with eroding the resin (A).

The type and the property values of the solvent (B1) shown in Table 1 are listed below. Note that the boiling point is a value at 101.3 kPa, and the vapor pressure is a value at 20° C.

(a) Diethylene glycol monoethyl ether acetate (boiling point: 217° C., vapor pressure: <0.01 kPa)
(b) Ethylene glycol monobutyl ether acetate (boiling point: 188° C., vapor pressure: 0.04 kPa)
(c) Diethylene glycol diethyl ether (boiling point: 189° C., vapor pressure: <0.1 kPa)
(d) γ-Butyrolactone (boiling point: 204° C., vapor pressure: <0.1 kPa)
(e) Methyl propylene diglycol (boiling point: 187° C., vapor pressure: <0.01 kPa)
(f) Methyl propylene triglycol (boiling point: 242° C., vapor pressure: <0.01 kPa)
(g) Butyl propylene diglycol (boiling point: 231° C., vapor pressure: 0.7 kPa)

Since the upper layer film-forming composition according to the embodiment of the present invention can suppress to dry out inside a nozzle between applications, the upper layer film-forming composition may suitably be used for a semiconductor production process that utilizes liquid immersion exposure. The method for forming a photoresist pattern according to the embodiment of the present invention may suitably be used for a semiconductor production process that utilizes liquid immersion exposure.

Obviously, numerous modifications and variations of the present invention are possible in light of the above teachings. It is therefore to be understood that within the scope of the appended claims, the invention may be practiced otherwise than as specifically described herein.

1. An upper layer film-forming composition comprising:
a resin soluble in a developer; and
a solvent component including a first solvent which has a boiling point of 180 to 280° C. at 101.3 kPa and a vapor pressure of 0.001 to 0.1 kPa at 20° C., the upper layer film-forming composition being used to form an upper layer film on a photoresist film.

2. The upper layer film-forming composition according to claim 1, wherein the first solvent is a compound shown by a general formula (1) or γ-butyrolactone, 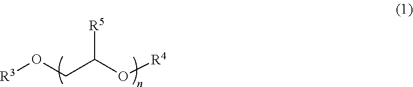
wherein n is an integer from 1 to 4, each of R³ and R⁴ individually represents a hydrogen atom, an alkyl group, or an acyl group, and R⁵ represents a hydrogen atom or a methyl group.

3. The upper layer film-forming composition according to claim 2, wherein the solvent component further includes a second solvent shown by a general formula (2),
R—OH (2)
wherein R represents a linear, branched, or cyclic hydrocarbon group having 1 to 10 carbon atoms or a halogenated hydrocarbon group.

4. The upper layer film-forming composition according to claim 3, wherein the solvent component further includes a third solvent shown by a general formula (3),
R¹—O—R² (3)
wherein each of R¹ and R² individually represents a hydrocarbon group having 1 to 8 carbon atoms or a halogenated hydrocarbon group.

5. The upper layer film-forming composition according to claim 1, wherein the first solvent is diethylene glycol monoethyl ether acetate, ethylene glycol monobutyl ether acetate, diethylene glycol diethyl ether, γ-butyrolactone, methyl propylene diglycol, methyl propylene triglycol or a mixture thereof.

6. The upper layer film-forming composition according to claim 4, wherein the first solvent is diethylene glycol monoethyl ether acetate, ethylene glycol monobutyl ether acetate, diethylene glycol diethyl ether, γ-butyrolactone, methyl propylene diglycol, methyl propylene triglycol or a mixture thereof.

7. The upper layer film-forming composition according to claim 1, wherein the resin includes a repeating unit having a group shown by a general formula (4), a repeating unit having a group shown by a general formula (5), a repeating unit having a group shown by a general formula (6), a repeating unit having a carboxyl group, a repeating unit having a sulfo group, or a combination thereof, and the resin has a polystyrene-reduced weight average molecular weight (Mw) determined by gel permeation chromatography of 2000 to 100,000, 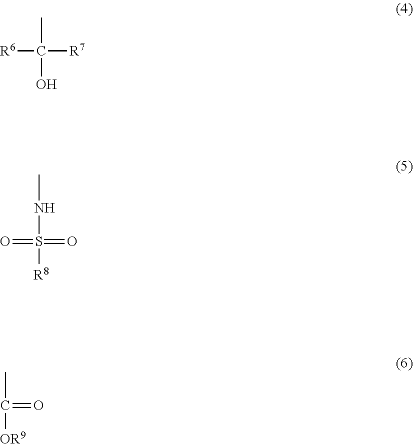
wherein
each of R⁶ and R⁷ individually represents a hydrogen atom, an alkyl group having 1 to 4 carbon atoms, or a fluoroalkyl group having 1 to 4 carbon atoms, wherein at least one of R⁶ and R⁷ represents a fluoroalkyl group having 1 to 4 carbon atoms,
R⁸ represents a fluoroalkyl group having 1 to 20 carbon atoms, and
R⁹ represents a fluorohydrocarbon group or an organic group having a polar group.

8. The upper layer film-forming composition according to claim 6, wherein the resin includes a repeating unit having a group shown by a general formula (4), a repeating unit having a group shown by a general formula (5), a repeating unit having a group shown by a general formula (6), a repeating unit having a carboxyl group, a repeating unit having a sulfo group, or a combination thereof, and the resin has a polystyrene-reduced weight average molecular weight (Mw) determined by gel permeation chromatography of 2000 to 100,000, 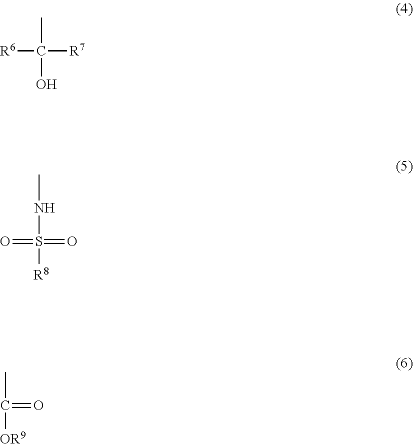
wherein
each of R⁶ and R⁷ individually represents a hydrogen atom, an alkyl group having 1 to 4 carbon atoms, or a fluoroalkyl group having 1 to 4 carbon atoms, wherein at least one of R⁶ and R⁷ represents a fluoroalkyl group having 1 to 4 carbon atoms,
R⁸ represents a fluoroalkyl group having 1 to 20 carbon atoms, and
R⁹ represents a fluorohydrocarbon group or an organic group having a polar group.

9. The upper layer film-forming composition according to claim 1, further comprising an acid component, an acid generating agent which generates an acid upon exposure to radiation, or both thereof.

10. The upper layer film-forming composition according to claim 6, further comprising an acid component, an acid generating agent which generates an acid upon exposure to radiation, or both thereof.

11. A method of forming a photoresist pattern comprising:
providing a photoresist film on a substrate;
providing an upper layer film on the photoresist film using the upper layer film-forming composition according to claim 1;
applying radiation to the upper layer film and the photoresist film through a mask having a given pattern via an immersion medium; and
developing the upper layer film and the photoresist film using a developer to form a photoresist pattern.

12. A method of forming a photoresist pattern comprising:
providing a photoresist film on a substrate;
providing an upper layer film on the photoresist film using the upper layer film-forming composition according to claim 6;
applying radiation to the upper layer film and the photoresist film through a mask having a given pattern via an immersion medium; and
developing the upper layer film and the photoresist film using a developer to form a photoresist pattern.
